(19) United States
(12) Patent Application Publication
(10) Pub. No.: US 2025/0248267 A1
(43) Pub. Date: Jul. 31, 2025

(54) DISPLAY DEVICE AND MANUFACTURING METHOD FOR THE SAME

(71) Applicant: Samsung Display Co., LTD., Yongin-si (KR)

(72) Inventor: BYUNGHOON KIM, Yongin-si (KR)

(21) Appl. No.: 19/040,302

(22) Filed: Jan. 29, 2025

(30) Foreign Application Priority Data
Jan. 31, 2024 (KR) 10-2024-0015141

(51) Int. Cl. H10K 59/80; H10H 29/01; H10H 29/80; H10H 29/855

(52) U.S. Cl. CPC H10K 59/871; H10H 29/034; H10H 29/842; H10H 29/8552; H10K 59/8792

(57) ABSTRACT

A manufacturing method for a display device includes providing a display panel, and forming, on the display panel, a coating window including an outer surface, where the forming the coating window on the display panel includes forming a preliminary coating window including a photocurable resin on the display panel, where the preliminary coating window is divided into a first preliminary portion and a second preliminary portion with a boundary surface therebetween, forming a cured surface by irradiating the boundary surface with light having a first wavelength, removing the second preliminary portion from the preliminary coating window, and curing the first preliminary portion by radiating light having a second wavelength which is smaller than the first wavelength onto the first preliminary portion.

This application claims priority to Korean Patent Application No. 10-2024-0015141, filed on Jan. 31, 2024, and all the benefits accruing therefrom under 35 U.S.C. § 119, the content of which in its entirety is herein incorporated by reference.

### BACKGROUND

### 1. Field

Embodiments of the disclosure herein relate to a display device and a manufacturing method for the coating window, and more particularly, to a display device including a coating window and a manufacturing method for the coating window.

### 2. Description of the Related Art

A display device such as a television, a monitor, a smartphone, and a tablet computer, which provides an image to a user, may include a display panel for displaying the image. Various display panels such as liquid crystal display panels, organic light-emitting display panels, electrowetting display panels, and electrophoretic display panels have been developed. In addition, the display device may include a window for protecting the display panel. The window may be attached to the display panel through a lamination process.

### SUMMARY

Embodiments of the disclosure provide a display device including a coating window.

Embodiments of the disclosure provide a manufacturing method for a display device including a coating window.

An embodiment of the invention provides a manufacturing method for a display device including providing a display panel, and forming a coating window on the display panel, where an outer surface of the coating window includes a rear surface adjacent to the display panel, a front surface opposed to the rear surface with respect to a thickness direction, and a side surface, at least a portion of which has a first curvature radius in a range of about 0.1 mm to about 5 mm from the front surface toward the rear surface, where the forming the coating window on the display panel includes forming a preliminary coating window including a photocurable resin, where the preliminary coating window is divided into a first preliminary portion and a second preliminary portion with a boundary surface therebetween, forming a cured surface by irradiating the boundary surface with light having a first wavelength, removing the second preliminary portion from the preliminary coating window, and curing the first preliminary portion by radiating light having a second wavelength which is smaller than the first wavelength onto the first preliminary portion.

In an embodiment, the forming the cured surface may be performed through two-photon polymerization.

In an embodiment, a thickness of at least a portion of the second preliminary portion may be greater than a thickness of the first preliminary portion.

In an embodiment, the light having the first wavelength may be visible light or infrared light.

In an embodiment, the light having the second wavelength may be ultraviolet light.

In an embodiment, the first wavelength may be in a range of about 680 nanometers (nm) to about 1030 nm.

In an embodiment, the second wavelength may be in a range of about 100 nm to about 400 nm.

In an embodiment, the forming the cured surface by irradiating the boundary surface with the light having the first wavelength may include performing a femtosecond laser beam process.

In an embodiment, in the femtosecond laser beam process, a laser pulse width may be in a range of about 0.01 picosecond (ps) to about 1 ps.

In an embodiment, the photocurable resin may be an ultraviolet (UV)-curable resin.

In an embodiment, the photocurable resin may include a siloxane-based resin.

In an embodiment of the invention, a display device includes a display panel and a coating window disposed on the display panel and including a first material, where an outer surface of the coating window includes a rear surface adjacent to the display panel, a front surface opposed to the rear surface with respect to a thickness direction, and a side surface, at least a portion of which has a first curvature radius in a range of about 0.1 mm to about 5 mm from the front surface toward the rear surface, and the first material includes a photocurable resin.

In an embodiment, the front surface of the coating window may include a transmission region and a bezel region adjacent to the transmission region, and the coating window may include a first portion overlapping the transmission region, and a second portion overlapping the bezel region.

In an embodiment, the first portion may include the first material, and the second portion may include the first material, and a second material which is a material obtained by overcuring the first material or is a material obtained by carbonizing the first material.

In an embodiment, the display device may further include a light blocking layer disposed under the second portion and including a light blocking material.

In an embodiment, the first material may include a UV-curable resin.

In an embodiment, the first material may include a photocurable siloxane-based resin.

In an embodiment, a surface roughness of the side surface may be substantially the same as a surface roughness of the front surface or a surface roughness of the rear surface.

In an embodiment, the side surface of the coating window may protrude further outwardly than a side surface of the display panel in a cross-sectional view.

In an embodiment, the display device may further include an optical layer disposed between the coating window and the display panel.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view of a display device according to an embodiment of the invention;

FIG. 2 is an exploded perspective view of a display device according to an embodiment of the invention;

FIG. 3 is a cross-sectional view of a display device according to an embodiment of the invention;

FIG. 4 is a cross-sectional view of a display panel according to an embodiment of the invention;

FIG. 5 is an enlarged cross-sectional view of a portion of a display device according to an embodiment of the invention;

FIGS. 6A and 6B are flowcharts showing some processes of a manufacturing method for a display device according to an embodiment of the invention; and

FIGS. 7A to 7D are cross-sectional views illustrating some processes of a manufacturing method for a display device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as being “on”, “connected to” or “coupled to” another element, it may be directly disposed on, connected or coupled to the other element, or an intervening element may be disposed therebetween. In contrast, when an element is referred to as being “directly on” another element, there are no intervening elements present.

Like reference numerals or symbols refer to like elements. Also, in the drawings, the thicknesses, ratios, and dimensions of the elements are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “part” and “unit” mean a software component or a hardware component for performing a specific function. The hardware component may include, for example, a field-programmable gate array (FPGA) or an application-specific integrated circuit (ASIC). The software component may refer to executable code and/or data used by executable code in an addressable storage medium. Thus, software components may be, for example, object-oriented software components, class components, and task components, and may include processes, functions, attributes, procedures, subroutines, program code segments, drivers, firmware, microcode, circuits, data, databases, data structures, tables, arrays, or variables.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

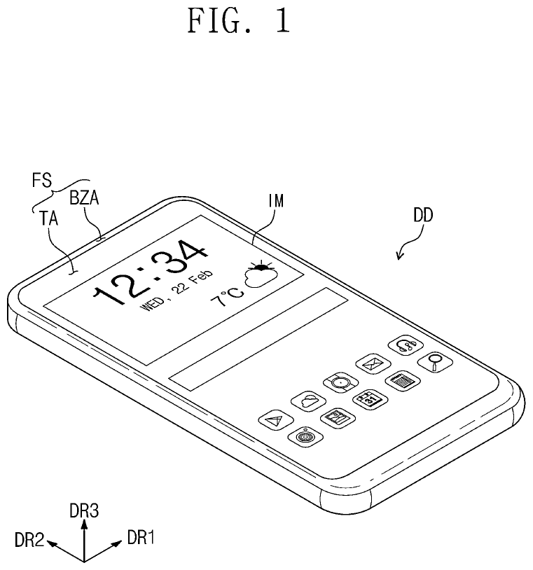

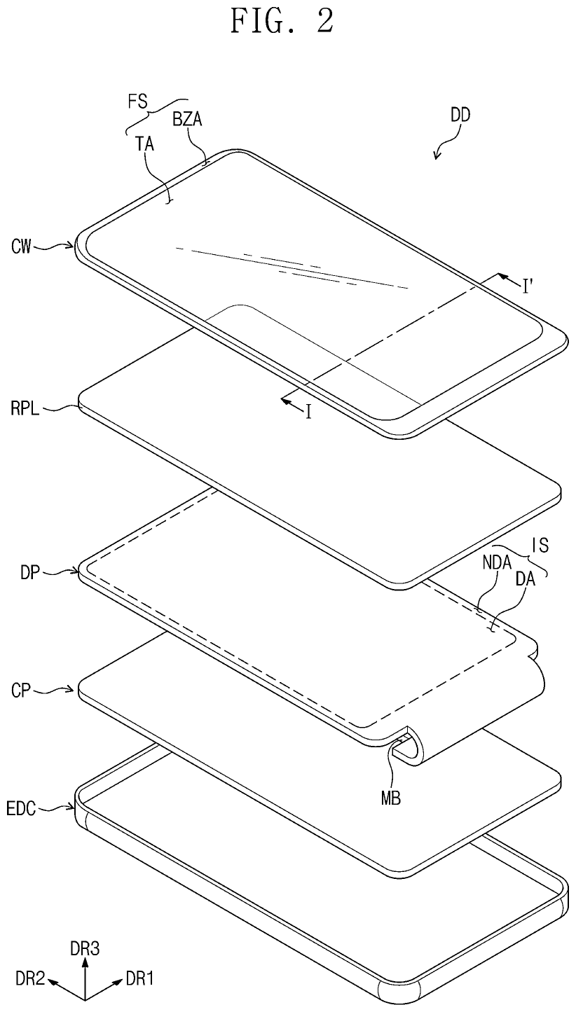

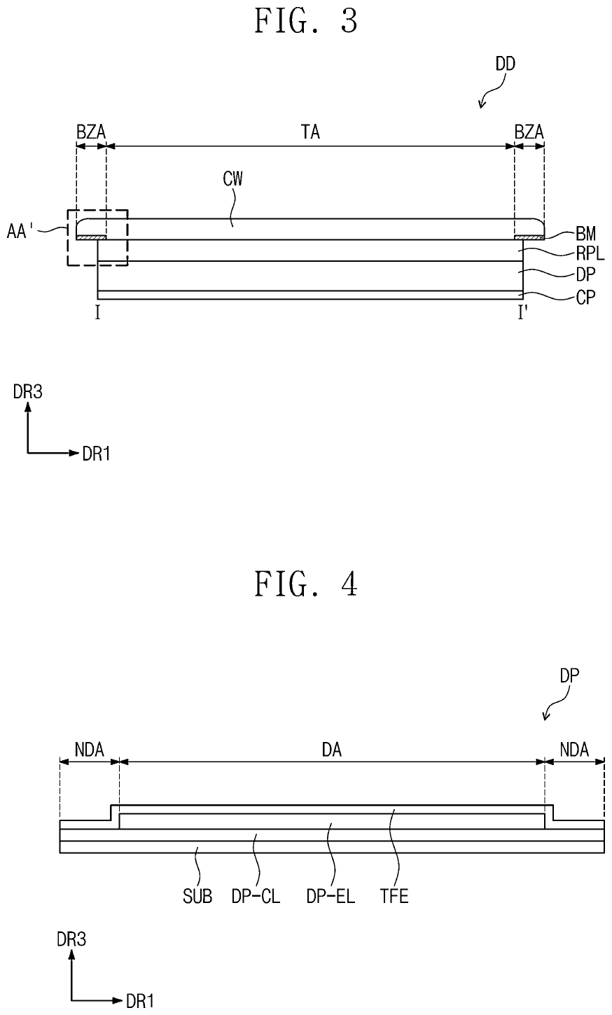

FIG. 1 is a perspective view of a display device DD according to an embodiment of the invention, and FIG. 2 is an exploded perspective view of a display device DD according to an embodiment of the invention. FIG. 3 is a cross-sectional view of a display device DD according to an embodiment of the invention. FIG. 3 illustrates a cross section taken along line I-I′ of FIG. 2.

Referring to FIGS. 1 and 2, an embodiment of the display device DD may be activated in response to an electrical signal and display an image. In an embodiment, for example, the display device DD may be included in a large-sized apparatus such as a television and an outdoor billboard, as well as a small- or medium-sized apparatus such as a monitor, a mobile phone, a tablet computer, a computer, a navigation device, and a game console. However, embodiments of the display device DD described herein are examples, and thus the display device DD is not limited to any one embodiment unless the display device DD departs from the scope of the invention. In an embodiment, for example, the display device DD may be a mobile phone as shown in FIG. 1.

Referring to FIG. 1, an embodiment of the display device DD may have a quadrangular shape having a rounded corner, short sides extending in a first direction DR1, and long sides extending in a second direction DR2 crossing the first direction DR1 in a plan view. However, an embodiment of the invention is not limited thereto, and the display device DD may have various shapes such as a rectangular shape, a square shape, a circular shape, a polygonal shape, and an arbitrary shape in a plan view.

The display device DD of an embodiment may be flexible. The term “flexible” may imply a bendable property, and the display device DD may be a device including any one from among a structure which is completely foldable to a structure which is bendable to a level of several nanometers. In an embodiment, for example, the flexible display device DD may include a curved display device, a foldable display device, a slidable display device, or a rollable display device. However, an embodiment of the invention is not limited thereto, and the display device DD may be rigid.

The display device DD may display an image IM in a third direction DR3 on a display surface parallel to each of the first direction DR1 and the second direction DR2. The third direction DR3 of the display device DD may be parallel to a thickness direction thereof crossing the first direction DR1 and the second direction DR2. The image IM provided from the display device DD may include a static image as well as a dynamic image. FIG. 1 illustrates a clock window and icons as an example of the image IM. The display surface on which the image IM is displayed may correspond to a front surface of the display device DD, and to a front surface FS of a coating window CW. Although FIG. 1 illustrates an embodiment having a flat display surface as an example, an embodiment of the invention is not limited thereto, and the display surface of the display device DD may also include a curved surface bent from at least one side of a plane.

A front surface (or an upper surface) and a rear surface (or a lower surface) of each member constituting the display device DD may be opposed to each other in the third direction DR3, and a normal direction of each of a front surface and a rear surface may be substantially parallel to the third direction DR3. A distance between a front surface and a rear surface defined along the third direction DR3 may correspond to a thickness of a member (or a unit). As used herein, the wording “in a plan view” may be defined as a state of being viewed in the third direction DR3. As used herein, the wording “in a cross-sectional view” may be defined as a state of being viewed in the first direction DR1 or the second direction DR2. Here, directions indicated by the first to third directions DR1, DR2, and DR3 may have a relative concept and may thus be changed to other directions.

Referring to FIGS. 2 and 3, an embodiment of the display device DD may include a coating window CW, an optical layer RPL, a display panel DP, a protective panel CP, and a case EDC. The coating window CW may be coupled to the case EDC to form an exterior of the display device DD.

The coating window CW may be disposed on the display panel DP. The coating window CW may have a shape corresponding to a shape of the display panel DP. The coating window CW may cover an entire outer side of the display panel DP and protect the display panel DP from an external impact and scratch.

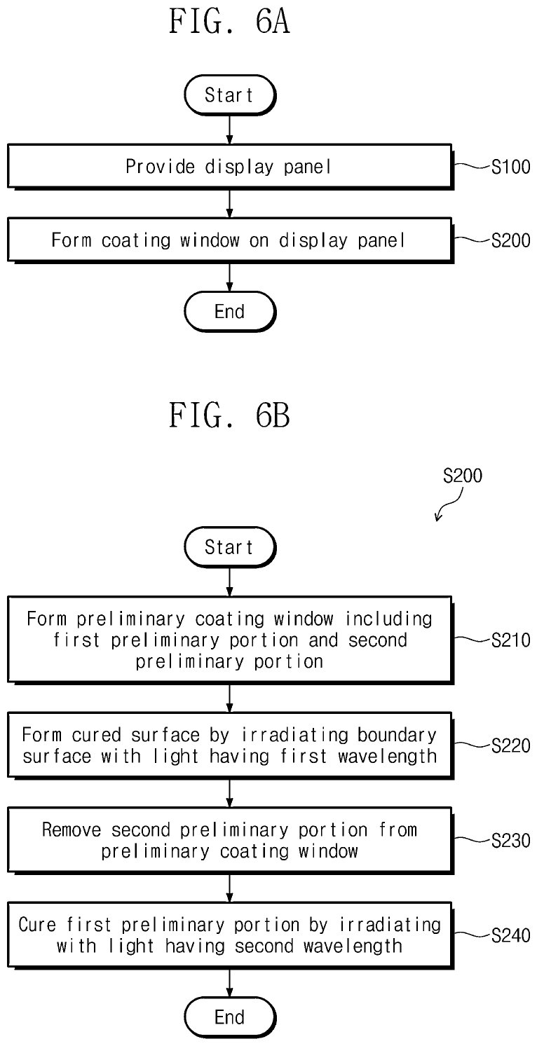

The coating window CW may include an optically transparent insulating material. The coating window CW may have a transmittance of about 90% or greater with respect to light in a visible light wavelength range. The coating window CW may have a transmittance of about 90% or greater with respect to light in a wavelength range of about 380 nanometers (nm) to about 780 nm. The coating window CW may have a single-layered or multi-layered structure. The coating window CW may further include one or more optically transparent functional layers. In an embodiment, for example, the coating window CW may further include functional layers such as an anti-fingerprint layer, a phase control layer, and a hard coating layer. A configuration of the coating window CW will be described in detail later with reference to FIG. 5.

A front surface FS of the coating window CW may include a transmission region TA and a bezel region BZA. The transmission region TA of the coating window CW may be an optically transparent region. The coating window CW may transmit the image IM provided by the display panel DP through the transmission region TA, such that a user may view the image IM.

The bezel region BZA of the coating window CW may effectively prevent a component of the display panel DP disposed to overlap the bezel region BZA from being viewed from the outside. The bezel region BZA of the coating window CW may overlap a light blocking layer BM. A side surface SS (see FIG. 5) of the coating window may protrude to the outside (or end) further than an outer side surface (or end) of the display panel DP. Accordingly, the light blocking layer BM may cover a non-display region NDA and the outside of the display panel DP.

The light blocking layer BM may include a predetermined light blocking material. The light blocking layer BM may include at least one selected from a colored color layer or a black light blocking layer. The light blocking layer BM may include a plurality of light blocking layers if desired. The light blocking layer BM may be formed on the coating window CW through a deposition, printing, coating process, or the like. In an embodiment, for example, the light blocking layer BM may be one achieved by printing ink including a light blocking component on the coating window CW.

The bezel region BZA may be adjacent to the transmission region TA. A shape of the transmission region TA may be substantially defined by the bezel region BZA. In an embodiment, for example, the bezel region BZA may be disposed outside the transmission region TA and surround the transmission region TA. However, this is illustrated as an example, and in another embodiment, the bezel region BZA may be adjacent to only one side of the transmission region TA or omitted. In addition, the bezel region BZA may be disposed on a side surface, not on a front surface, of the display device DD.

The optical layer RPL may be disposed between the display panel DP and the coating window CW. The optical layer RPL may reduce reflectance for light incident from the outside. In an embodiment, the optical layer RPL may include a retarder and/or a polarizer. The optical layer RPL may include at least a polarizing film. In such an embodiment, the optical layer RPL may be attached to the display panel DP through an adhesive layer. However, this is an example, and an embodiment of the invention is not limited thereto. In another embodiment, for example, the optical layer RPL may include a color filter.

The display panel DP may be disposed between the coating window CW and the protective panel CP. The display panel DP may display an image in response to an electrical signal. The display panel DP according to an embodiment may be an emissive display panel, but is not particularly limited thereto. In an embodiment, for example, the display panel DP may be an organic light-emitting display panel, an inorganic light-emitting display panel, an organic-inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the organic-inorganic light-emitting display panel may include an organic-inorganic light-emitting material. An emission layer of the quantum dot light-emitting display panel may include quantum dots, quantum rods, etc.

The image IM provided by the display device DD may be displayed on a front surface IS of the display panel DP. The front surface IS of the display panel DP may include a display region DA and a non-display region NDA. The display region DA may be a region which is activated in response to an electrical signal and in which an image is displayed. According to an embodiment, the display region DA of the display panel DP may correspond to the transmission region TA of the coating window CW. As used herein, “a region/portion and a region/portion correspond to each other” means “regions/portions overlap each other” and is not limited to a case in which regions/portions have a same area size and/or a same shape as each other.

The non-display region NDA may be adjacent to an outer side of the display region DA. In an embodiment, for example, the non-display region NDA may surround the display region DA. However, an embodiment of the invention is not limited thereto, and the non-display region NDA may be defined in various shapes.

The non-display region NDA may be a region in which a driving line or a driving circuit for driving elements disposed in the display region DA, various types of signal lines for providing an electrical signal, pads, etc. are disposed. The non-display region NDA of the display panel DP may correspond to the bezel region BZA of the coating window CW. Components of the display panel DP disposed in the non-display region NDA may be effectively prevented from being viewed from the outside by the bezel region BZA.

The display device DD may include a circuit board MB connected to the display panel DP. The circuit board MB may be connected to one end of the display panel DP extending in a first direction DR1. The circuit board MB may generate an electrical signal which is provided to the display panel DP. In an embodiment, for example, the circuit board MB may include a timing controller which generates a signal provided to a driver of the display panel DP in response to control signals received from the outside.

At least a portion of the non-display region NDA of the display panel DP may be bent. A portion of the display panel DP to which the circuit board MB is connected may be bent so that the circuit board MB faces a rear surface of the display panel DP. The circuit boar MB may be disposed and assembled so as to overlap the rear surface of the display panel DP in a plan view. However, an embodiment of the invention is not limited thereto, and in another embodiment, the display panel DP and the circuit board MB may be connected to each other through a flexible circuit board connected to one end of each of the display panel DP and the circuit board MB.

The protective panel CP may be disposed on a lower surface of the display panel DP. The protective panel CP may protect the display panel DP from an impact transferred from below. FIG. 5 illustrates the protective panel CP as a single layer for convenience of illustration, but the protective panel CP may have a multi-layered structure including a barrier layer, a cushion layer, or the like. The barrier layer of the protective panel CP may have a color having a low light transmittance, thereby preventing components under the barrier layer from being viewed. The cushion layer of the protective panel CP may be disposed on the barrier layer and absorb an impact transferred from below the display panel DP. The cushion layer of the protective panel CP may include or be made of a material having high elasticity such as a foam sheet in which a plurality of openings are formed.

The case EDC may provide an inner space capable of accommodating components of the display device DD. The case EDC may be disposed below the display panel DP and accommodate the display panel DP. The case EDC may include glass, plastic, or a metal material having relatively high rigidity. The case EDC may protect the display panel DP by absorbing an impact applied from the outside or preventing foreign substances/moisture, etc. from infiltrating into the display panel DP.

The display device DD according to an embodiment may further include an input sensing layer which is disposed on the display panel DP and senses an external input applied from the outside. The input sensing layer may sense an external input in various forms such as force, pressure, temperature, and light provided from the outside. In an embodiment, for example, the input sensing layer may sense a contact by a pen or a user's body provided from outside the display device DD, an input (e.g., hovering) applied close to the display device DD, or the like.

In addition, an electronic apparatus according to an embodiment of the invention may include the display device DD and an electronic module including various functional modules for operating the display panel DP and a power supply module for supplying power required for the display device DD. In an embodiment, for example, the electronic apparatus may include a camera module as an example of the electronic module.

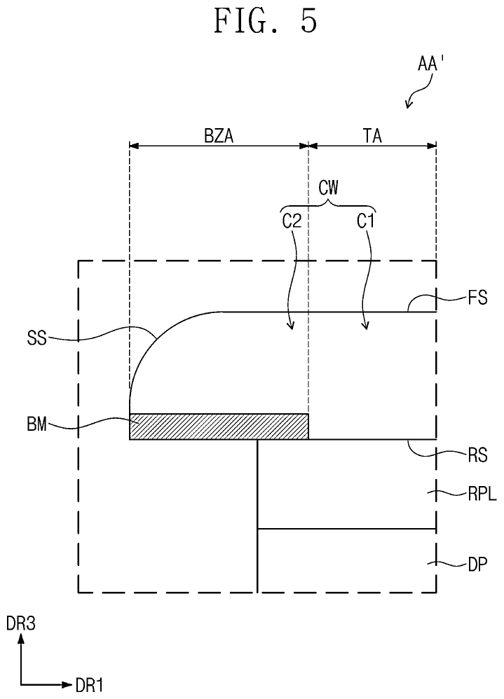

FIG. 4 is a cross-sectional view of a display panel DP according to an embodiment of the invention.

The display panel DP according to an embodiment of the invention may be an emissive display panel, and is not particularly limited. In an embodiment, for example, the display panel DP may be an organic light-emitting display panel, an inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include quantum dots, quantum rods, etc. Hereinafter, for convenience of description, embodiments where the display panel DP is an organic light-emitting display panel will be mainly described.

In an embodiment, as shown in FIG. 4, the display panel DP may include a base layer SUB, a display element layer DP-EL, a circuit layer DP-CL, and an encapsulation layer TFE. The display panel DP according to the invention may be a flexible display panel. However, an embodiment of the invention is not limited thereto. For example, the display panel DP may be a foldable display panel which is folded with respect to a folding axis or a rigid display panel.

The base layer SUB may provide a base surface on which the circuit layer DP-CL is disposed. The base layer SUB may be a flexible substrate capable of being bent, folded, rolled, etc. The base layer SUB may be a glass substrate, a metal substrate, a polymer substrate, or the like. However, an embodiment of the invention is not limited thereto, and the base layer SUB may include an inorganic layer, an organic layer, or a composite material layer.

The base layer SUB may include a single layer or a plurality of layers. In an embodiment, for example, the base layer SUB may include a first synthetic resin layer, a multi-layered or single-layered inorganic layer, and a second synthetic resin layer disposed on the multi-layered or single-layered inorganic layer. Each of the first synthetic resin layer and the second synthetic resin layer may include a polyimide-based resin. Also, each of the first synthetic resin layer and the second synthetic resin layer may include at least one selected from an acrylic resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. As used herein, a “˜˜ based” resin may be considered as including a functional group of “˜˜”.

The circuit layer DP-CL is disposed between the base layer SUB and the display element layer DP-EL. The circuit layer DP-CL includes at least one insulating layer and a circuit element. Hereinafter, an insulating layer included in the circuit layer DP-CL will be referred to as an intermediate insulating layer. The intermediate insulating layer includes at least one intermediate inorganic layer and at least one intermediate organic layer. The circuit element may include a pixel driving circuit included in each of a plurality of pixels for displaying an image. The circuit layer DP-CL may further include signal lines connected to the pixel driving circuit and/or a sensor driving circuit.

The display element layer DP-EL may include a light-emitting element included in each of the pixels. The light-emitting element may be provided in plurality, and the plurality of light-emitting elements may correspond to a plurality of light-emitting regions. In an embodiment, for example, the plurality of light-emitting regions may include a red light-emitting region, a green light-emitting region, and a blue light-emitting region.

The encapsulation layer TFE may be disposed on the display element layer DP-EL and encapsulate the display element layer DP-EL. The encapsulation layer TFE may include at least one organic layer and at least one inorganic layer. The inorganic layer may include an inorganic material and protect the display element layer DP-EL from moisture/oxygen. The inorganic layer may include a silicon nitride layer, a silicon oxynitride layer, a silicon oxide layer, a titanium oxide layer, an aluminum oxide layer, or the like, but is not particularly limited thereto. The organic layer may include an organic material and protect the display element layer DP-EL from foreign substances such as dust particles.

FIG. 5 is an enlarged cross-sectional view of a portion of a display device according to an embodiment of the invention. FIG. 5 illustrates an enlarged cross section corresponding to a region AA′ of FIG. 3. FIG. 5 is a cross-sectional view illustrating the coating window CW according to an embodiment of the invention in greater detail.

Referring to FIG. 5, an outer surface of the coating window CW includes a front surface FS, a rear surface RS, and a side surface SS. The front surface FS of the coating window CW may correspond to the front surface of the display device DD on which the image IM (see FIG. 1) is displayed. The rear surface RS of the coating window CW may be a surface adjacent to the display panel DP in the third direction DR3. The rear surface RS of the coating window CW may be defined as a surface opposed to the front surface FS of the coating window CW in the third direction DR3.

The coating window CW includes at least one side surface SS, and the side surface SS of the coating window CW has a first curvature radius (or first radius of curvature). The first curvature radius may be defined as a minimum value of a radius of a circular arc which is closest to a curved surface along all directions from one point on the side surface SS of the coating window CW. The first curvature radius may be in a range of about 0.1 millimeter (mm) to about 5 mm. In an embodiment, for example, the first curvature radius may be in a range of about 1 mm to about 5 mm.

In an embodiment, surface roughness of the side surface SS of the coating window CW may be substantially the same as surface roughness of the front surface FS or the rear surface RS of the coating window CW. As used herein, the wording “substantially the same” includes not only a case in which components have physically completely the same surface roughness, etc., but also a case in which, despite the same design, there is a difference therebetween which falls within a margin of error in a process. When the coating window CW according to an embodiment of the invention is manufactured, the side surface SS of the coating window CW may not be physically damaged. Accordingly, the side surface SS of the coating window CW may have a same level of a surface roughness value as another outer surface of the coating window CW.

The coating window CW includes a first material of a photocurable resin material. The first material may include an ultraviolet (UV)-curable resin material. In an embodiment, for example, the first material may include a UV-curable siloxane-based resin material. In such an embodiment, the coating window CW may be formed by a process of applying a liquid resin composition. Since the coating window CW may be formed by applying a liquid resin composition, the coating window CW may not include a glass substrate. A typical display device is manufactured by providing a window including a glass substrate on a display panel. The window including the glass substrate is typically attached onto the display panel through a lamination process using an adhesive member for attaching the window. In an embodiment, the coating window CW formed through a liquid composition may be performed without an attaching process, an adhesive member, etc., thereby contributing to improving manufacturing efficiency and reducing a thickness of a display device.

The coating window CW may include a first portion C1 and a second portion C2. The first portion C1 may overlap the transmission region TA of the front surface FS, and the second portion C2 may overlap the bezel region BZA of the front surface FS. The first portion C1 may be a portion corresponding to the transmission region TA of the front surface FS, and the second portion C2 may be a portion corresponding to the bezel region BZA of the front surface FS. A side surface of the second portion C2 may correspond to the side surface SS of the coating window CW, and the side surface of the second portion C2 may substantially define the side surface SS of the coating window CW.

The first portion C1 of the coating window CW and the second portion C2 of the coating window CW may each include the first material of a photocurable resin. The second portion C2 may include the first material of a photocurable resin and may further include a second material different from the first material. The second material may be a material obtained by carbonizing at least a portion of the first material. Alternatively, the second material may be a material obtained by overcuring at least a portion of the first material. In such an embodiment where the second portion C2 includes the second material, at least a portion of the second portion C2 may be formed by a process in which the first material of a photocurable resin is overcured or carbonized. When the coating window CW according to an embodiment of the invention is manufactured, a portion of the side surface SS of the coating window CW may be overcured or carbonized. However, an embodiment of the invention is not limited thereto, and the coating window CW may not include the second material, and the first portion C1 and the second portion C2 may each include only the first material.

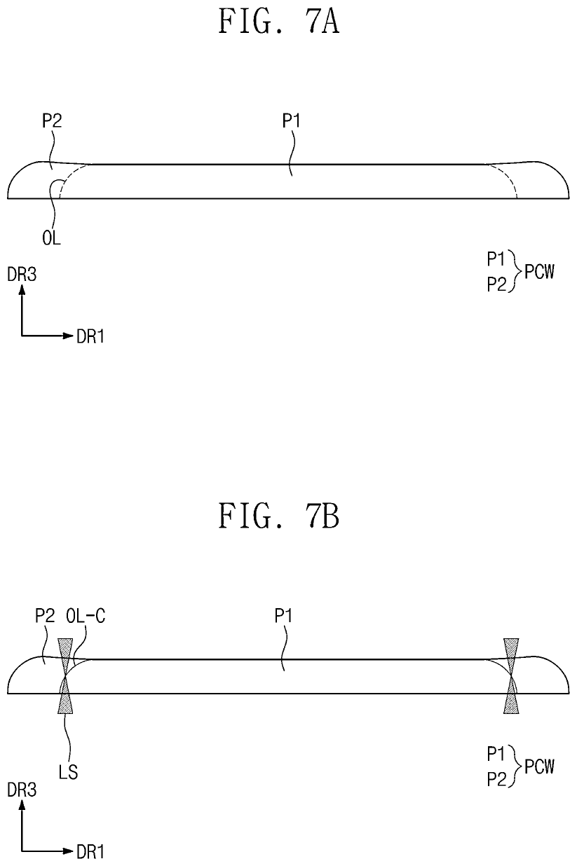

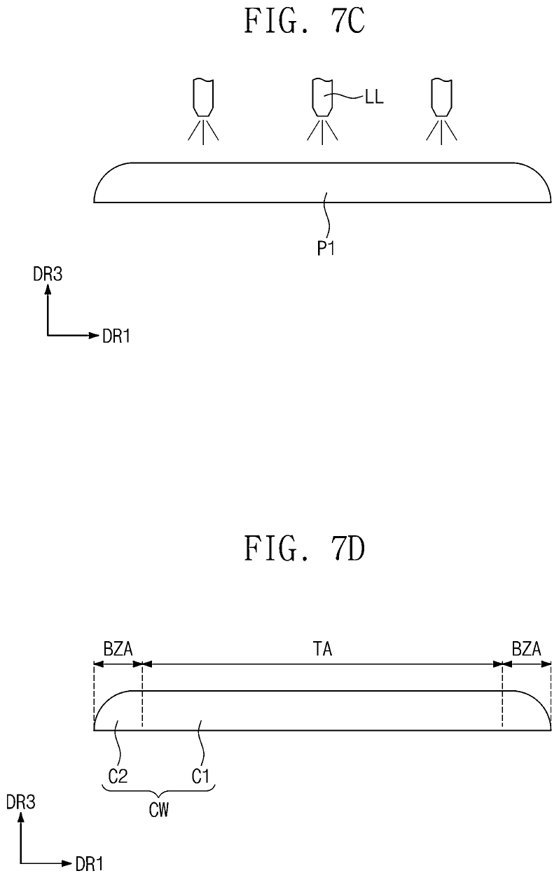

Hereinafter, a manufacturing method for a display device DD according to an embodiment of the invention will be described with reference to FIGS. 6A, 6B, and 7A to 7D.

FIG. 6A is a flowchart showing some processes of a manufacturing method for a display device according to an embodiment of the invention. FIG. 6B is a flowchart showing forming a coating window in a manufacturing method for a display device according to an embodiment of the invention. FIGS. 7A to 7D are cross-sectional views illustrating some processes of a manufacturing method for a display device according to an embodiment of the invention. In describing a manufacturing method for a display device according to an embodiment of the invention, the same component as the component described above will be denoted as the same reference numerals or symbols, and any repetitive detailed description thereof will be omitted or simplified.

Referring to FIG. 6A, the manufacturing method for the display device according to an embodiment of the invention includes providing (or preparing) a display panel (S100), and forming a coating window on the display panel (S200). Referring to FIG. 6B, the forming of the coating window (S200) in the manufacturing method for the display device according to an embodiment of the invention may include forming a preliminary coating window including a first preliminary portion and a second preliminary portion (S210), forming a cured surface by irradiating a boundary surface with light having a first wavelength (S220), removing the second preliminary portion from the preliminary coating window (S230), and curing the first preliminary portion by irradiating with light having a second wavelength (S240).

FIGS. 7A to 7D are schematic drawings showing the forming of the coating window (S200) in the manufacturing method for the display device according to an embodiment. FIG. 7A schematically shows the forming of the preliminary coating window including the first preliminary portion and the second preliminary portion (S210), FIG. 7B schematically shows the forming of the cured surface by irradiating the boundary surface with the light having the first wavelength (S220), FIG. 7C schematically shows the removing of the second preliminary portion from the preliminary coating window (S230), and FIG. 7D schematically shows the curing of the first preliminary portion by irradiating with the light having the second wavelength (S240).

Referring to FIGS. 6B and 7A, the manufacturing method for the display device according to an embodiment of the invention includes forming a preliminary coating window PCW including a first preliminary portion P1 and a second preliminary portion P2 (S210).

The forming of the preliminary coating window PCW (S210) may include providing a liquid resin composition. In an embodiment, the forming of the preliminary coating window PCW (S210) may include applying the liquid resin composition through a nozzle. In an embodiment, the forming of the preliminary coating window PCW (S210) may include performing an inkjet process or a jet dispensing process. The liquid resin composition may include a photocurable resin material. The liquid resin composition may include a UV-curable resin material and include a siloxane-based resin material.

The preliminary coating window PCW may include the first preliminary portion P1 and the second preliminary portion P2. The first preliminary portion P1 may correspond to a coating window CW (see FIG. 7D) to be described later, and the second preliminary portion P2 may surround the first preliminary portion P1 in a plan view. The first preliminary portion P1 and the second preliminary portion P2 may be divided from each other by a boundary surface OL between the first preliminary portion P1 and the second preliminary portion P2. The boundary surface OL may be defined as one side surface shared by the first preliminary portion P1 and the second preliminary portion P2. The boundary surface OL may correspond to a side surface SS (see FIG. 7D) of a coating window CW (see FIG. 7D) to be described later.

A thickness of the first preliminary portion P1 may be substantially even in a plan view. The thickness of the first preliminary portion P1 may be substantially constant along a first direction DR1 and a second direction DR2. In an embodiment, the first preliminary portion P1 may have a flat upper surface in a plan view. A thickness of the second preliminary portion P2 may be uneven in a plan view. In an embodiment, the second preliminary portion P1 may have a curved upper surface in a plan view. The thickness of the second preliminary portion P2 may be relatively great or relatively small compared to any average value thereof. A thickness of at least a portion of the second preliminary portion P2 may be relatively great compared to the thickness of the first preliminary portion P1. The preliminary coating window PCW may be formed through applying liquid composition, and only a thickness of the second preliminary portion P2 adjacent to an outer periphery may thus become uneven due to surface tension of liquid, etc.

Referring to FIGS. 6B, 7A, and 7B, the manufacturing method for the display device according to an embodiment of the invention includes forming a cured surface OL-C by irradiating the boundary surface OL with light having first wavelength (S220).

The cured surface OL-C may be a surface formed by photocuring the boundary surface OL through light having the first wavelength. The boundary surface OL may include a liquid photocurable resin composition, and the cured surface OL-C may be a surface formed by curing the liquid photocurable resin composition. In an embodiment, for example, the cured surface OL-C may be a surface formed by curing a UV-curable resin composition.

The light having the first wavelength may be visible light or infrared light. The first wavelength may be in a range of about 400 nm to about 2000 nm. In an embodiment, tor example, the first wavelength may be in a range of about 680 nm to about 1030 nm.

The forming of the cured surface OL-C(S220) may include irradiating the boundary surface OL with a laser LS which emits light having the first wavelength. The forming of the cured surface OL-C(S220) may include irradiating one point with a plurality of lasers LS at the same time. One point may be irradiated with the plurality of lasers LS, and light having the first wavelength which is provided in plurality to the one point may be combined. The laser LS, which emits the light having the first wavelength that may be visible light or infrared light, may be provided in plurality or several times, and the cured surface OL-C may thus be substantially UV-cured.

The irradiating of the boundary surface OL with the laser LS which emits the light having the first wavelength may include performing a femtosecond laser beam process. In the femtosecond laser beam process, a laser pulse width may be in a range of about 0.01 picosecond (ps) to about 1 ps.

The forming of the cured surface OL-C(S220) may include curing the boundary surface OL through two-photon polymerization (2PP) using light having the first wavelength. That is, the forming of the cured surface OL-C(S220) may be a process of three dimensional (3D)-printing the cured surface OL-C using two-photon polymerization.

Referring to FIGS. 6B and 7B to 7D, the manufacturing method for the display device according to an embodiment of the invention includes removing the second preliminary portion P2 from the preliminary coating window PCW (S230), and curing the first preliminary portion P1 by irradiating with light having a second wavelength (S240).

The second preliminary portion P2 may be removed from the preliminary coating window PCW. The second preliminary portion P2 may be separated from the first preliminary portion P1 at the cured surface OL-C, and the separated second preliminary portion P2 may be removed. The second preliminary portion P2 may not be included in a coating window CW (see FIG. 7D) to be described later.

The first preliminary portion P1 may be photocured with light having the second wavelength. The first preliminary portion P1 may be UV-cured by a UV lamp LL. The UV lamp LL may be provided above the first preliminary portion P1, and the UV lamp LL may emit light having the second wavelength. The light having the second wavelength may be ultraviolet light. The second wavelength may be smaller than the first wavelength. The second wavelength may be in a range of about 100 nm to about 400 nm. The coating window CW may be one formed by photocuring the first preliminary portion P1.

When a display device including a coating window is manufactured, in applying a liquid resin composition, an outer peripheral portion may have an uneven thickness compared to a central portion due to surface tension. A manufacturing method for a display device according to an embodiment of the invention may include forming a preliminary coating window by applying a liquid resin composition and then forming a cured surface through two-photon polymerization, and removing a second preliminary portion through the cured surface, thereby providing a display device having improved thickness evenness and improved reliability. In addition, even if a second portion of a coating window overlapping a bezel region has a certain curvature in a display device of an embodiment, a manufacturing method for a display device of an embodiment may include a 3D printing process using two-photon polymerization, thereby providing a coating window having improved reliability.

A display device according to an embodiment of the invention may include a coating window, and a lamination process may thus be skipped, thereby simplifying a manufacturing process and reducing cost.

A manufacturing method for a display device according to an embodiment of the invention may include forming a cured surface and then removing a second preliminary portion, thereby providing a coating window having improved thickness evenness. Thus, a display device having improved reliability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A manufacturing method for a display device, the manufacturing method comprising:
providing a display panel; and
forming a coating window on the display panel, wherein an outer surface of the coating window includes a rear surface adjacent to the display panel, a front surface opposed to the rear surface with respect to a thickness direction, and a side surface, at least a portion of which has a first curvature radius in a range of about 0.1 mm to about 5 mm from the front surface toward the rear surface,
wherein the forming the coating window on the display panel includes:
forming a preliminary coating window including a photocurable resin, wherein the preliminary coating window is divided into a first preliminary portion and a second preliminary portion with a boundary surface therebetween;
forming a cured surface by irradiating the boundary surface with light having a first wavelength;
removing the second preliminary portion from the preliminary coating window; and
curing the first preliminary portion by radiating light having a second wavelength, which is smaller than the first wavelength, onto the first preliminary portion.

2. The manufacturing method of claim 1, wherein the forming the cured surface is performed through two-photon polymerization.

3. The manufacturing method of claim 1, wherein a thickness of at least a portion of the second preliminary portion is greater than a thickness of the first preliminary portion.

4. The manufacturing method of claim 1, wherein the light having the first wavelength is visible light or infrared light.

5. The manufacturing method of claim 1, wherein the light having the second wavelength is ultraviolet light.

6. The manufacturing method of claim 1, wherein the first wavelength is in a range of about 680 nm to about 1030 nm.

7. The manufacturing method of claim 1, wherein the second wavelength is in a range of about 100 nm to about 400 nm.

8. The manufacturing method of claim 1, wherein the forming the cured surface by irradiating the boundary surface with the light having the first wavelength comprises performing a femtosecond laser beam process.

9. The manufacturing method of claim 8, wherein in the femtosecond laser beam process, a laser pulse width is in a range of about 0.01 ps to about 1 ps.

10. The manufacturing method of claim 1, wherein the photocurable resin is a UV-curable resin.

11. The manufacturing method of claim 1, wherein the photocurable resin comprises a siloxane-based resin.

12. A display device comprising:
a display panel; and
a coating window disposed on the display panel, and including a first material,
wherein an outer surface of the coating window includes
a rear surface adjacent to the display panel,
a front surface opposed to the rear surface with respect to a thickness direction, and
a side surface of which at least a portion has a first curvature radius in a range of about 0.1 mm to about 5 mm from the front surface toward the rear surface, and
the first material includes a photocurable resin.

13. The display device of claim 12, wherein the front surface of the coating window comprises a transmission region and a bezel region adjacent to the transmission region, and
the coating window comprises a first portion overlapping the transmission region, and a second portion overlapping the bezel region.

14. The display device of claim 13, wherein the first portion comprises the first material, and
the second portion comprises the first material, and a second material which is a material obtained by overcuring the first material or is a material obtained by carbonizing the first material.

15. The display device of claim 13, further comprising:
a light blocking layer disposed under the second portion, and including a light blocking material.

16. The display device of claim 12, wherein the first material comprises a UV-curable resin.

17. The display device of claim 12, wherein the first material comprises a photocurable siloxane-based resin.

18. The display device of claim 12, wherein a surface roughness of the side surface is substantially the same as a surface roughness of the front surface or a surface roughness of the rear surface.

19. The display device of claim 12, wherein the side surface of the coating window protrudes further outwardly than a side surface of the display panel in a cross-sectional view.

20. An electronic apparatus which provides an image,
the electronic apparatus comprising a display device a power supply module for supplying power to the display device,
the display device comprising:
a display panel; and
a coating window disposed on the display panel, and including a first material,
wherein an outer surface of the coating window includes
a rear surface adjacent to the display panel,
a front surface opposed to the rear surface with respect to a thickness direction, and
a side surface of which at least a portion has a first curvature radius in a range of about 0.1 mm to about 5 mm from the front surface toward the rear surface, and
the first material includes a photocurable resin.
